(19) United States
(12) Patent Application Publication
(10) Pub. No.: US 2014/0049274 A1
(43) Pub. Date: Feb. 20, 2014

(54) SYSTEM FOR MEASURING MATERIAL LEVELS USING CAPACITANCE AND TIME DOMAIN REFLECTOMETRY SENSORS

(71) Applicant: Kevin G. Hafer, Douglassville, PA (US)

(72) Inventor: Kevin G. Hafer, Douglassville, PA (US)

(73) Assignee: AMETEK, INC., Berwyn, PA (US)

(21) Appl. No.: 14/113,866

(22) PCT Filed: Apr. 30, 2012
(86) PCT No.: PCT/US12/35767

§ 371 Date: Oct. 25, 2013

Related U.S. Application Data
(60) Provisional application No. 61/480,796, filed on Apr. 29, 2011.

(51) Int. Cl. G01R 27/26

(52) U.S. Cl. CPC G01R 27/2605
USPC 324/681

(57) ABSTRACT

An apparatus and system for measuring levels of two or more materials maintained within a storage tank using a combination of both a capacitance sensor and a time domain reflectometry (“TDR”) waveguide sensor is disclosed. The apparatus includes a combined circuit for the capacitance sensor and TDR sensor that creates a separation between the return signal from the capacitance sensor and the TDR sensor. The need for the return signal separation is due to the generation of false reflection signals from the capacitance circuitry. In a preferred embodiment, the separation in time is created by moving the capacitance false reflections further in time than the true signal returns. An alternative preferred embodiment would delay the true TDR signals passed the capacitance false reflections. Another alternative preferred embodiment would provide a substantially matched impedance of the capacitance circuit to the TDR circuit, to substantially eliminate the false reflections.

### FIELD OF THE INVENTION

The invention generally relates to sensors and systems used to measure material levels within tanks or vessels. More particularly, the disclosed invention relates to a hybrid apparatus or system using a capacitance sensor in combination with a time domain reflectometry (“TDR”) waveguide sensor to measure the levels of two or more materials, or the levels of a single material having phase differences, where the material or materials are stored within a tank or vessel. The invention also describes a method of using the hybrid apparatus or system to appropriately measure the multiple material levels by separating the real return signals from the false reflections that may be created by the capacitance circuits.

In a preferred embodiment, the inventive apparatus is a combination or hybrid of capacitance sensor technology and TDR sensor technology, along with associated circuitry for generating pulse signals and sensing return signals from the TDR element along with sensing the capacitance sensor signal. Because a pulsed signal will generate a false reflection from the capacitance sensor circuitry, the inventive apparatus and system use electronic circuitry to create a separation in time between the true return signals from the anticipated false reflection signals from the capacitance sensor.

### BACKGROUND OF THE INVENTION

The need to measure the level of fluids or materials stored or maintained in tanks or vessels has led to the development of different devices to accurately measure such material levels. Example known devices that are used to measure material levels within vessels include capacitance sensors and TDR sensors or probes. Each of these technologies (capacitance and TDR) has certain attributes and advantages, as well, not unexpectedly, certain limitations in where they may be used, and with respect to the types of materials they may be used to measure levels. For example, as such devices are currently manufactured and commercialized, a level of single material may be accurately measured using either a capacitance sensor or a TDR sensor depending upon the material being measured and its physical properties. However, the ability to measure more than one level within a tank, due to there being more than one material or fluid in the tank, or there being a distinction in the phase of a single material (e.g., fluid vs. foam), is limited.

Different systems have attempted to address the issue of measuring multiple levels within a tank or vessel. Two such devices are described in U.S. Pat. No. 6,481,276 (the “'276 patent”) and U.S. patent application Ser. No. 12/735,119 (the “'119 application”). Both of these devices or apparatus have particular limitations. For example, the '276 patent discloses a device for measuring the filling level of a material in a container using a sensor and a control/evaluation unit such that the sensor may be operated in at least two different measurement methods, including a capacitive measurement method or a guided radio-frequency measurement method. As disclosed in the '276 patent, including as shown in FIG. 1 of the '276 patent, the device requires a switching circuit that alternatively connects the capacitive circuit or the radio-frequency circuit to the sensor.

Similarly, the '119 application describes an apparatus for measuring at least one fill level of at least one medium in a container using a travel-time measuring method and/or a capacitive measuring method by means of a least one measuring probe. As specifically provided in the '119 application, the apparatus requires a diplexer that transmits the low-frequency signal and the high-frequency signal, and effects a signal separation of the high frequency signal to the travel-time measuring circuit, and the low frequency signal to the capacitive measuring circuit.

Current material measuring systems using both a TDR and capacitive measurement method that do not rely upon a diplexer or some other form of switching or signal separation circuit do not appear to exist. Indeed, the effective and useable combination of a capacitance sensor with a TDR sensor, that does not depend upon or use a diplexer or switching mechanism has not, to date, been achieved. The current invention, as described below, teaches such an apparatus, system and method.

### SUMMARY OF THE INVENTION

The above noted problems, which are inadequately or incompletely resolved by the prior art are completely addressed and resolved by the present invention.

A preferred aspect of the present invention is an apparatus for measuring two or more levels of materials stored in a tank or vessel, comprising a capacitance sensor and first related circuitry; and a TDR sensor and second related circuitry; wherein a separation in time between a return signal from the capacitance sensor and a return signal from the TDR sensor is created using the first and the second related circuitry.

Another preferred aspect of the present invention is an apparatus for measuring two or more levels of materials stored in a tank or vessel, comprising a capacitance sensor and first related circuitry; and a time domain reflectometry sensor and second related circuitry; wherein the first related circuitry comprises a matching impedance circuit to substantially eliminate false reflection signals from the capacitance circuitry.

Still another preferred aspect of the present invention is an apparatus for measuring two or more levels of a single material stored in a tank or vessel, comprising a capacitance sensor and first related circuitry; and a time domain reflectometry sensor and second related circuitry; wherein a separation in time between a return signal from the capacitance sensor and a return signal from the TDR sensor is created using the first and the second related circuitry.

Yet another preferred aspect of the present invention is a system for measuring two or more levels of materials stored in a tank or vessel, comprising at least one material measuring probe; a capacitance sensor; first circuitry associated with the capacitance sensor; a TDR sensor; and second circuitry associated with the TDR sensor; wherein a separation in time between a return signal from the capacitance sensor and a return signal from the TDR sensor is created using the first and second related circuitry.

And a further preferred aspect of the present invention is a method for measuring at least one phase level of at least one material stored in a tank or vessel, where such method uses a capacitance sensor and time domain reflectometry sensor to measure the at least one phase level, the method comprising the steps of (a) transmitting a signal to the capacitance sensor to measure the at least one phase level; (b) transmitting a signal to the TDR sensor to measure the at least one phase level; and (c) separating in time a return signal from the capacitance sensor from a return signal from the TDR sensor.

### BRIEF DESCRIPTION OF THE DRAWINGS

The invention is best understood from the following detailed description when read in connection with the accompanying drawings. It is emphasized that, according to common practice, the various features of the several drawings are not to scale, and the invention is not limited to the precise arrangement as may be shown in the accompanying drawings. On the contrary, the dimensions and locations of the various features are arbitrarily expanded or reduced for clarity, unless specifically noted in the attached claims.

FIG. 1: is a circuit diagram showing an example prior art material level measurement circuit using capacitance measurement signals;

FIG. 2: is a preferred embodiment of a hybrid circuit using both capacitive sensor and TDR sensor circuitry, along with an element to delay in time the capacitive reflection signals;

FIG. 3: is a preferred embodiment of a hybrid circuit using both capacitive sensor and TDR sensor circuitry, along with an element to delay in time the TDR reflection signals;

FIG. 4A: is an illustration of the false return signal from the capacitance circuitry without use of the inventive delay element; and

FIG. 4B: is an illustration of the time delayed false return signal using an embodiment of the inventive delay element.

### DETAILED DESCRIPTION OF PREFERRED EMBODIMENTS

The present invention is an apparatus, system and method for measuring the levels of one or more materials stored in vessel, or for measuring the levels of a single material store in a vessel where that material has one or more phases. A detailed description of various preferred embodiments of the inventive apparatus, systems and methods is provided in this specification.

As described above, both capacitance sensors and TDR sensors are well-known and are used to independently measure material levels for materials that are stored within vessels or tanks. Moreover, both capacitance sensors and TDR sensors have inherent advantages and disadvantages that must be considered in determining the best apparatus or system (be it a capacitance sensor or a TDR sensor) for a particular measurement application.

While certain measuring devices or systems have combined a capacitance sensor and a TDR sensor, such devices and systems have specifically required, and relied upon a diplexer or switching mechanism to select which of the two sensors are to be used. The combined use of a capacitance sensor, with a TDR sensor, that does not rely upon use of a diplexer or switching means has not, to date, been achieved.

As disclosed by the present invention, through the use of particular electronic circuitry to separate signals received from the capacitance sensor and the TDR sensor, accurate measurement of two levels of a material, or two or more materials within a tank can be accurately achieved. The present invention is such an apparatus or system that uses both a capacitance sensor and a TDR sensor to measure the levels of two or more materials, which are typically fluids, that are stored in a tank or vessel. The inventive apparatus or system can also be used to measure two phase levels of one material where the material may have distinct phases, such a fluid phase and a lower density foam phase.

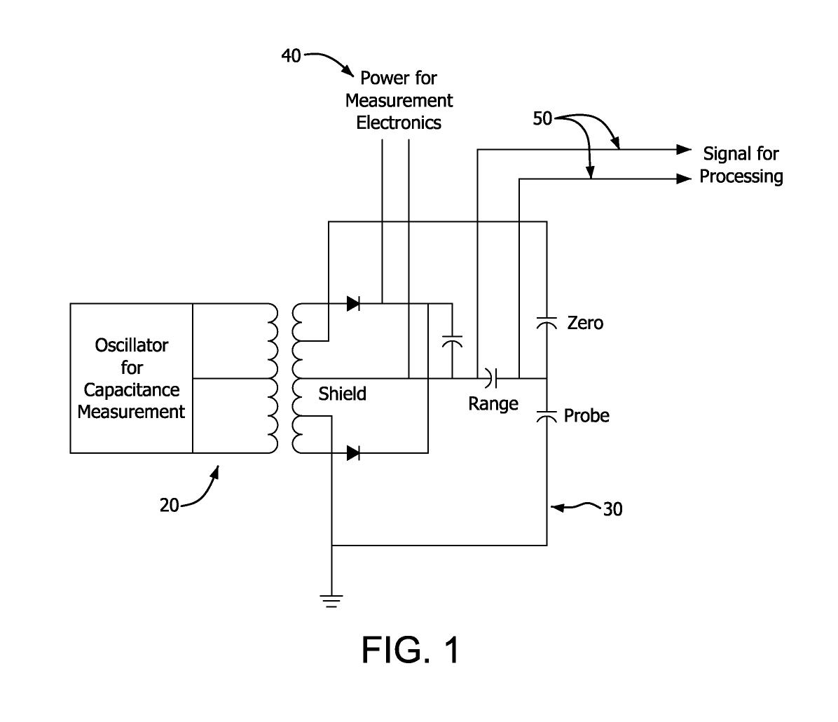

By way of background, and only for comparison purposes, an example embodiment of a prior art capacitance sensor circuit is shown in FIG. 1. The capacitance sensor circuit includes an oscillator 20 used for the capacitance measurement. There is also related probe circuitry 30 to measure the variation in capacitance as a function of the material level within the vessel. More specifically, as the material level may vary within the vessel, the measured capacitance will similarly vary. The capacitance sensor circuit also have power leads 40 to provide electrical power to the measurement electronics. Finally, the prior art circuit includes an output signal 50 from the probe for processing and calculation of the material level that is measured by the capacitance sensor.

Capacitance Return Signal Delay

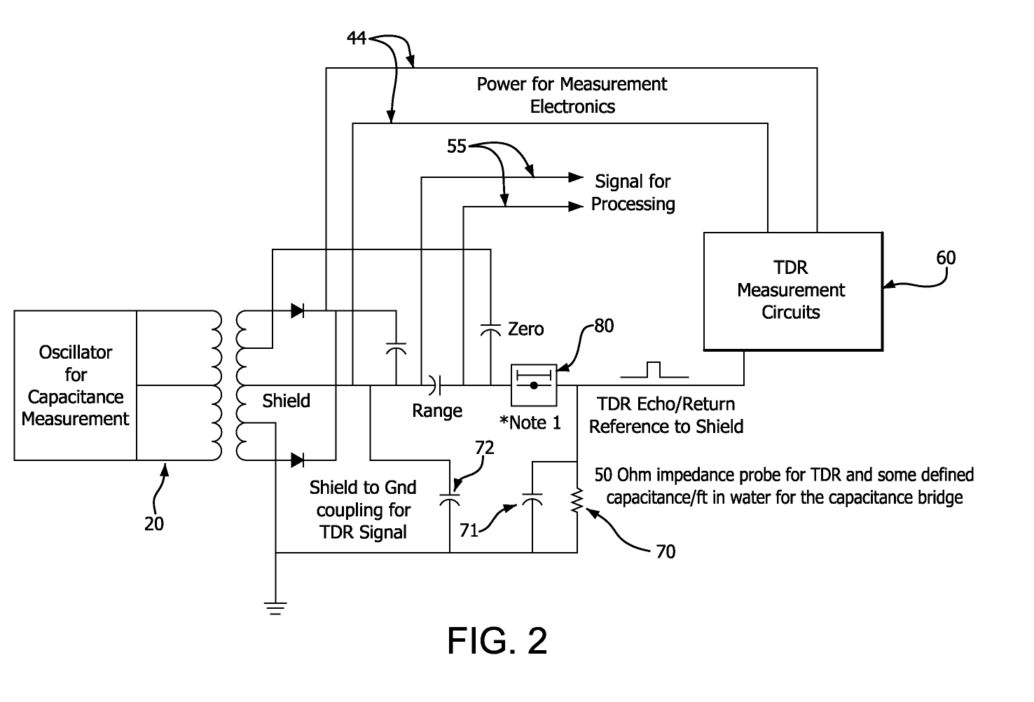

In a preferred embodiment of the present invention, a hybrid capacitance sensor and a TDR sensor circuit is shown in FIG. 2. Similar to that shown in FIG. 1, the elements for the capacitance sensor circuit include first an oscillator 20 used as part of the capacitance measurement. The TDR sensor element of the apparatus includes independent TDR measurement circuitry 60. As compared to the capacitance sensor circuitry 30 shown in FIG. 1, the hybrid apparatus of the present invention includes combining circuitry 33 that electrically connects the capacitance sensor and TDR sensor.

As shown in FIG. 2, certain additional circuit elements are provided within the hybrid sensor to permit connection of the two sensors. First, in a preferred embodiment, a resistor 70 is shown for the 50 ohm TDR probe. In other embodiments and applications, other size resistors (other than 50 ohms) may be used. Second, a capacitor 71 is shown for use as a capacitance bridge. Third, a capacitor 72 is provided for the shield to ground coupling for the TDR signal.

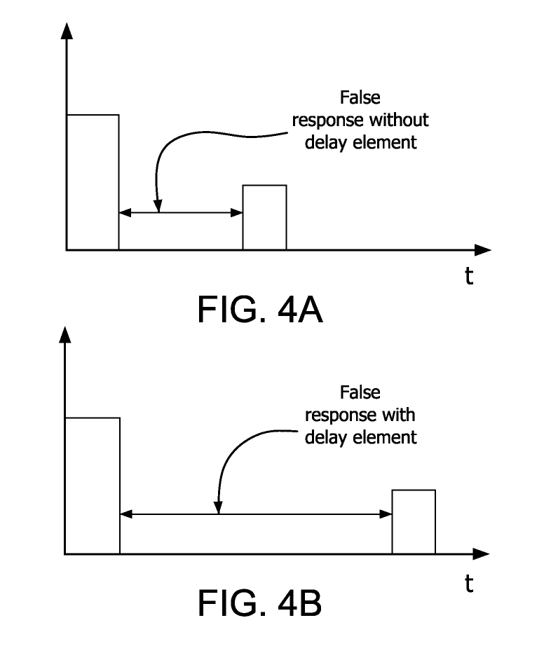

To ensure that the true return signal from the TDR probe is not masked or confused with a false reflection signal received from the capacitance sensor, a means of separating, in time, the false return signals needs to be incorporated within the circuit. As illustrated in FIG. 2, by the Note 1, a means may be included to delay the false reflection signal from the capacitance circuitry. In an exemplary embodiment, a length of cable 80, which may be a length of coaxial cable, can be incorporated between the TDR measurement circuits 60 and the capacitance circuitry 33. By implementing such a length of cable, a time delay is created for the false reflection signals from the capacitance electronics. The time delay is created simply because the signal must travel over a longer length of coaxial cable. FIGS. 4A and 4B illustrate an example of the time delay of the false return from the capacitance circuitry through use of a length of cable in the apparatus.

The length of the cable 80 may be selected to ensure that the false reflections are far enough separated in time from the expected true signal return measurement time. As noted, one embodiment for delaying the false reflection signal, is the use of a length of coaxial cable. However, other means of delaying the false reflections, including electronic means, may be implemented and effectively used.

As further shown in FIG. 2, power leads 44 for the measurement electronics are provided for both the capacitance sensor and the TDR sensor to provide electrical power to both sensors. Finally, the output signal 55, shown in FIG. 2, provides the output signal of the hybrid apparatus that is then used to process and calculate the material(s) levels. Such output signals are generally sent to a processor (not shown) for appropriate interpretation and calculation of material levels or phase levels of a material.

TDR Signal Delay

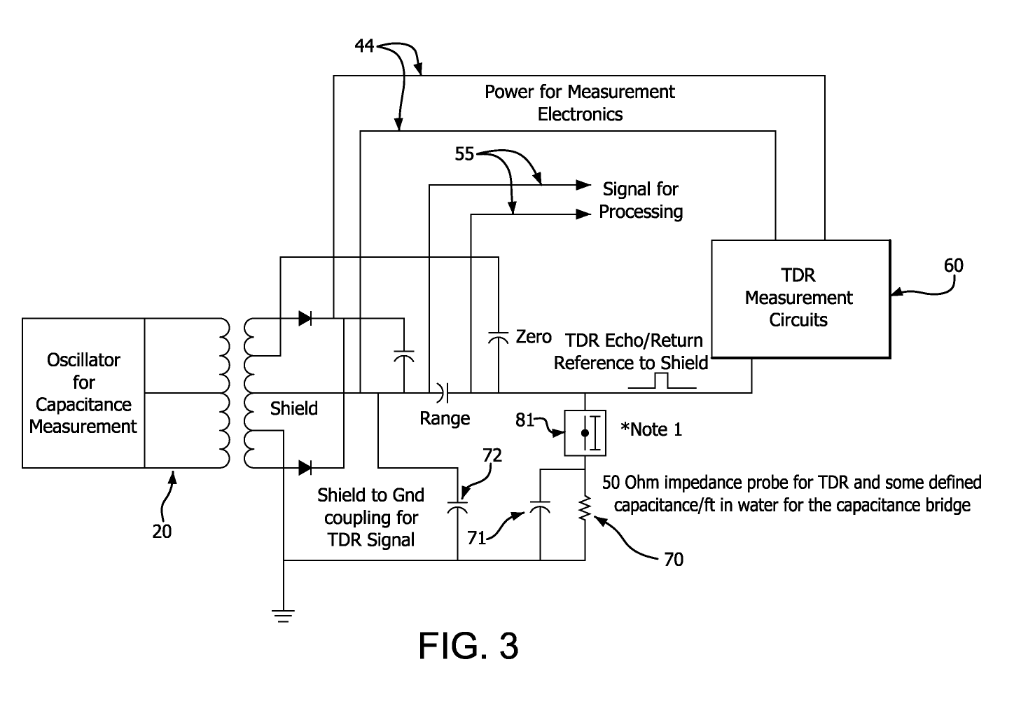

In another preferred embodiment of the inventive hybrid apparatus, a different means of separating the capacitance sensor false return signal from the TDR sensor, is shown in FIG. 3. The hybrid capacitance sensor and TDR sensor circuitry shown in FIG. 3 has a similar circuitry and configuration to that shown in FIG. 2, but is critically different in the means of separating the capacitance sensor and TDR sensor signals.

More particularly, the FIG. 3 apparatus similarly includes an oscillator for the capacitance sensor measurement, and similarly includes the TDR measurement circuitry 60. The inventive hybrid sensor apparatus as shown in FIG. 3 also has circuitry 33 (similar to that shown in FIG. 2) connecting the capacitance sensor and TDR sensor. Further, the FIG. 3 embodiment incorporates a resistor 70 for the TDR probe, and a capacitor 71 for the capacitance bridge. As noted above, the resistor 70 is shown as a 50 ohm resistor, however, other size resistors may be used in different applications where smaller or larger resistances are warranted. Finally, as also shown in the FIG. 2 circuit, the embodiment illustrated in FIG. 3 includes a capacitor 72 provided for the shield to ground for the TDR signal.

An important difference between the embodiment shown in FIG. 2, and the FIG. 3 embodiment is the placement of the delay means within the circuit. As shown in FIG. 3, the delay means 81 (illustrated as “Note 1”) is included between the TDR measurement circuits 60 on one side, and the TDR probe 70 and capacitance bridge 71 on the other side. Note, by way of comparison, that the incorporation of the delay means 80 in FIG. 2 was between the TDR measurement circuits 60 and the capacitance circuitry 33.

By incorporating the delay means 81, as shown in FIG. 3, between the TDR measurement circuits 60 and the TDR probe 70, the separation of the false reflections received from the capacitance sensor and the true signals from the TDR probe is provided by delaying in time the true TDR signals. In a preferred embodiment, such a delay means 81 may, similar to that described above, be a length of coaxial cable or other means of retarding the true TDR signal. The appropriate length of cable can be easily determined by calculation of the amount of time that a false reflection would be expected, and then providing for a time delay of the TDR signal by an appropriate amount beyond such false reflections. By way of one example, it is known that the false reflections from the capacitance sensor are usually within the first one or two feet of measurement, while the true signal return from the TDR probe are within the approximate range of 50 feet of measurement. Such a substantial difference, here an order of magnitude difference, in the “distance” measured for the material levels provides a straightforward means for separating the false return from the true measured return.

Impedance Matching

Another preferred embodiment of the inventive hybrid apparatus, that does not depend upon delay of either the capacitance return signal or the TDR return signal, incorporates additional circuitry within the capacitance circuit. More particularly, the capacitance circuit is terminated with a substantially matched impedance (to the TDR sensor) to effectively remove false reflection signals from the capacitance circuit. Through such matching of impedance within the capacitance circuit substantially results in there being no false reflection signals from the capacitance circuit. This alternative preferred embodiment of the present invention is different from the above FIG. 2 and FIG. 3 embodiments because the delay means (being either elements 80 or 81), being in one embodiment, a length of cable, can be eliminated. Through the elimination of a length of cable, the hybrid apparatus or system, is less complex and less costly.

The above detailed description provides certain examples of the hybrid capacitance and TDR sensor circuitry. Another aspect of the claimed invention is a hybrid sensor system that uses the disclosed hybrid capacitance and TDR sensor circuitry apparatus. Such a system includes all elements necessary for a complete measurement system, including the sensor or probe. Those additional system elements include, only by way of example, electrical power to power the measurement electronics, a processor to interpret and calculate level measurements from the output signals 55, and a display to provide the output of the level measurements for the user to interpret.

In other aspects of the claimed invention, alternative methods for using a hybrid capacitance and TDR sensor may be used. Such methods provide appropriate steps to implement means to delay either the capacitance sensor false return, or the TDR true return, as described above, and thereby ensure that false reflection signals are not confused with the true level measurement signals. The FIG. 2 and FIG. 3 circuitry illustrate preferred embodiments of the elements and steps necessary to separate the false return signals from the true return signals.

While particular circuits and systems have been described and illustrated to show preferred embodiments of the hybrid capacitance and TDR sensor apparatus, other similar circuitry, systems and means are understood to be within the scope of this disclosure. For example, as noted, other means for delaying either the false reflections from the capacitance sensor, or delaying the true signals from the TDR sensor may be incorporated other than use of a length of cable.

What is claimed is:

1. An apparatus for measuring two or more levels of materials stored in a tank or vessel, comprising:
a capacitance sensor and first related circuitry; and
a time domain reflectometry (“TDR”) sensor and second related circuitry;
wherein a separation in time between a return signal from the capacitance sensor and a return signal from the TDR sensor is created using the first and the second related circuitry.

2. The apparatus for measuring two or more levels of materials stored in a tank or vessel, as described in claim 1, wherein the separation in time between a return signal from the capacitance sensor and a return signal from the TDR sensor is created using only the first related circuitry.

3. The apparatus for measuring two or more levels of materials stored in a tank or vessel, as described in claim 1, wherein the separation in time between a return signal from the capacitance sensor and a return signal from the TDR sensor is created using only the second related circuitry.

4. The apparatus for measuring two or more levels of materials stored in a tank or vessel, as described in claim 1, wherein the separation in time between a return signal from the capacitance sensor and a return signal from the TDR sensor is created by delaying in time the return signal from the capacitance sensor.

5. The apparatus for measuring two or more levels of materials stored in a tank or vessel, as described in claim 1, wherein the separation in time between a return signal from the capacitance sensor and a return signal from the TDR sensor is created by delaying in time the return signal from the TDR sensor.

6. An apparatus for measuring two or more levels of materials stored in a tank or vessel, comprising:
a capacitance sensor and first related circuitry; and
a time domain reflectometry (“TDR”) sensor and second related circuitry;
wherein the first related circuitry comprises a matching impedance circuit to substantially eliminate false reflection signals from the capacitance circuitry.

7. An apparatus for measuring two or more levels of a single material stored in a tank or vessel, comprising:
a capacitance sensor and first related circuitry; and
a time domain reflectometry (“TDR”) sensor and second related circuitry;
wherein a separation in time between a return signal from the capacitance sensor and a return signal from the TDR sensor is created using the first and the second related circuitry.

8. A system for measuring two or more levels of materials stored in a tank or vessel, comprising:
at least one material measuring probe;
a capacitance sensor;
first circuitry associated with the capacitance sensor;
a time domain reflectometry (“TDR”) sensor; and
second circuitry associated with the TDR sensor;
wherein a separation in time between a return signal from the capacitance sensor and a return signal from the TDR sensor is created using the first and second related circuitry.

9. The system for measuring two or more levels of materials stored in a tank or vessel, as described in claim 8, wherein the separation in time between a return signal from the capacitance sensor and a return signal from the TDR sensor is created using only the first related circuitry.

10. The system for measuring two or more levels of materials stored in a tank or vessel, as described in claim 8, wherein the separation in time between a return signal from the capacitance sensor and a return signal from the TDR sensor is created using only the second related circuitry.

11. The system for measuring two or more levels of materials stored in a tank or vessel, as described in claim 8, wherein the separation in time between a return signal from the capacitance sensor and a return signal from the TDR sensor is created by delaying in time the return signal from the capacitance sensor.

12. The system for measuring two or more levels of materials stored in a tank or vessel, as described in claim 8, wherein the separation in time between a return signal from the capacitance sensor and a return signal from the TDR sensor is created by delaying in time the return signal from the TDR sensor.

13. A system for measuring two or more levels of materials stored in a tank or vessel, comprising:
at least one material measuring probe;
a capacitance sensor;
first circuitry associated with the capacitance sensor;
a time domain reflectometry (“TDR”) sensor; and
second circuitry associated with the TDR sensor;
wherein the first related circuitry comprises a matching impedance circuit to substantially eliminate false reflection signals from the capacitance circuitry.

14. A system for measuring two or more levels of single material stored in a tank or vessel, comprising:
at least one material measuring probe;
a capacitance sensor;
first circuitry associated with the capacitance sensor;
a time domain reflectometry (“TDR”) sensor; and
second circuitry associated with the TDR sensor;
wherein a separation in time between a return signal from the capacitance sensor and a return signal from the TDR sensor is created using the first and second related circuitry.

15. A method for measuring at least one phase level of at least one material stored in a tank or vessel, where such method uses a capacitance sensor and time domain reflectometry (“TDR”) sensor to measure the at least one phase level, the method comprising the steps of:
(a) transmitting a signal to the capacitance sensor to measure the at least one phase level;
(b) transmitting a signal to the TDR sensor to measure the at least one phase level; and
(c) separating in time a return signal from the capacitance sensor from a return signal from the TDR sensor.

16. The method for measuring at least one phase level of at least one material stored in a tank or vessel, as described in claim 15, where step (c) is separating in time a return signal from the capacitance sensor from a return signal from the TDR sensor by delaying in time the return signal from the capacitance sensor.

17. The method for measuring at least one phase level of at least one material stored in a tank or vessel, as described in claim 15, where step (c) is separating in time a return signal from the capacitance sensor from a return signal from the TDR sensor by delaying in time the return signal from the TDR sensor.
